(19) United States
(12) Patent Application Publication
(10) Pub. No.: US 2024/0061651 A1
(43) Pub. Date: Feb. 22, 2024

(54) Contention-Based Random-Number Generator

(71) Applicant: NUVOTON TECHNOLOGY CORPORATION, Hsin-chu (TW)

(72) Inventors: Ziv Hershman, Givat Shmuel (IL); Tamir Golan, Kibbutz Givaat-Chaim Meuchad (IL)

(21) Appl. No.: 17/892,173

(22) Filed: Aug. 22, 2022

(51) Int. Cl. G06F 7/58

(52) U.S. Cl. CPC G06F 7/58

(57) ABSTRACT

An electronic circuit for Random Number Generation (RNG) includes multiple inverters, a contention-current generator, and digitization circuitry. The multiple inverters are connected to one another in a ring and configured to generate an oscillating signal. The contention-current generator is connected to a node at which an output of an inverter of the ring drives an input of a subsequent inverter of the ring with a drive current. The contention-current generator includes at least a buffer configured to drive the node, at least while a voltage at the node transitions between opposite logic states, with a contention current that opposes the drive current and is weaker than the drive current. The digitization circuitry is configured to generate a sequence of random numbers by sampling the oscillating signal generated in the ring.

### FIELD OF THE INVENTION

The present invention relates generally to random-number generation circuits, and particularly to contention-based random-number generation.

### BACKGROUND OF THE INVENTION

Various circuits and techniques for random number generation are known in the art. Some Random Number Generator (RNG) circuits are based on ring oscillators. For example, U.S. Pat. No. 4,905,176 describes a random number generator that is invulnerable to cryptographic attack. The principle of operation of the random number generator is based upon low-frequency sampling of the output of a pseudo-random number generator which is operated at a varying frequency from a free-running ring oscillator.

### SUMMARY OF THE INVENTION

An embodiment of the present invention that is described herein provides an electronic circuit for Random Number Generation (RNG) including multiple inverters, a contention-current generator, and digitization circuitry. The multiple inverters are connected to one another in a ring and configured to generate an oscillating signal. The contention-current generator is connected to a node at which an output of an inverter of the ring drives an input of a subsequent inverter of the ring with a drive current. The contention-current generator includes at least a buffer configured to drive the node, at least while a voltage at the node transitions between opposite logic states, with a contention current that opposes the drive current and is weaker than the drive current. The digitization circuitry is configured to generate a sequence of random numbers by sampling the oscillating signal generated in the ring.

In an embodiment, the contention-current generator includes a bus holder. In another embodiment, an input of the buffer of the contention-current generator is driven by an output of a downstream inverter of the ring. In an example embodiment, the downstream inverter is the subsequent inverter in the ring.

In a disclosed embodiment, the buffer in the contention-current generator has a weaker drive strength than the inverter generating the drive current. In an embodiment, the contention current is weaker than the drive current by no more than a predefined ratio. In some embodiments, the electronic circuit further includes a calibration circuit, which is configured to calibrate one or both of (i) the inverter of the ring and (ii) the buffer in the contention-current generator, so as to ascertain that the contention current is weaker than the drive current by no more than a predefined ratio.

There is additionally provided, in accordance with an embodiment that is described herein, a method for Random Number Generation (RNG) including generating an oscillating signal using multiple inverters that are connected to one another in a ring. A contention-current generator, which includes at least a buffer connected to a node at which an output of an inverter of the ring drives an input of a subsequent inverter of the ring with a drive current, is used for driving the node, at least while a voltage at the node transitions between opposite logic states, with a contention current that opposes the drive current and is weaker than the drive current. A sequence of random numbers is generated by sampling the oscillating signal generated in the ring.

The present invention will be more fully understood from the following detailed description of the embodiments thereof, taken together with the drawings in which:

### BRIEF DESCRIPTION OF THE DRAWINGS

FIGS. 1 and 2 are block diagrams that schematically illustrate contention-based Random-Number Generators (RNGs), in accordance with embodiments of the present invention;

FIGS. 3A-3C are histograms showing simulated performance of a contention-based RNG in accordance with an embodiment of the present invention, and of two non-contention-based RNGs for comparison;

FIG. 4 is a flow chart that schematically illustrates a method for random-number generation, in accordance with an embodiment of the present invention; and

FIG. 5 is a block diagram that schematically illustrates a calibration circuit for a contention-current generator, in accordance with embodiments of the present invention.

### DETAILED DESCRIPTION OF EMBODIMENTS

### Overview

Embodiments of the present invention that are described herein provide improved Random-Number Generation (RNG) circuits and associated methods. In the disclosed embodiments, an RNG circuit comprises a free-running ring oscillator, i.e., an odd number of inverters connected in a ring and configured to generate an oscillating signal. A digitization circuit is configured to generate a sequence of random numbers by sampling the oscillating signal generated in the ring. Since the ring oscillator is free running and contains a certain amount of intrinsic noise, sampling the oscillating signal, typically at a low sampling rate, yields a random-number sequence.

In practice, the randomness of the random-number sequence depends on the amount of time jitter in the cycle period of the oscillating signal generated by the ring oscillator. When the cycle period has a considerable time jitter, sampling the oscillating signal will yield a high degree of randomness, and vice versa. In some embodiments of the present invention, the RNG circuit further comprises one or more contention-current generators that enhance the time jitter (i.e., increase the variability) of the oscillating signal's cycle period.

Consider a circuit node that connects the output of a given inverter in the ring to the input of the subsequent inverter. The given inverter drives the node with a certain drive current. In an embodiment, a contention-current generator is connected to the node. The contention-current generator is configured to drive the node, at least during transition periods of the oscillating signal at the node, with a contention current that (i) opposes the drive current and (ii) is weaker than the drive current. The term “transition periods” refers to the time periods in which the oscillating signal transitions between values corresponding to logic “0” and values corresponding to logic “1”.

The first condition (the contention current opposes the drive current) causes the time jitter of the oscillating signal to increase. The second condition (the contention current is weaker than the drive current) ensures that the inverters in the ring will continue alternating (“flipping”), i.e., that the ring oscillator will continue oscillating.

In some embodiments, every node of the ring (i.e., the output of every inverter in the ring) has a respective contention-current generator coupled thereto. In other embodiments, respective contention-current generators may be coupled to a subset of the ring nodes, or even a single node.

In various embodiments, the contention-current generators may be implemented in various ways. In one embodiment, a contention-current generator comprises a bus holder, i.e., a pair of inverters connected back-to-back. In another embodiment, a contention-current generator comprises an inverter connected in a feedback connection, i.e., driven by the output of the subsequent ring inverter. More generally, the contention-current generator typically comprises at least a buffer that drives the node with contention current. In the present context, an inverter is considered a type of buffer.

The increased time jitter achieved by the disclosed techniques can be exploited in various ways. For example, for a given level of randomness, a random-number sequence can be generated at a faster rate, because a higher-frequency ring cycle with the same jitter per cycle can be achieved, or alternately a ring having the same frequency with increased level of randomness per cycle can be achieved, or both. Put differently, for a ring having a given frequency, the oscillating signal can be sampled with a higher sampling rate, thus generating random numbers at a higher rate, while retaining the same level of randomness.

Example performance of the disclosed RNG circuits is demonstrated herein using simulated histograms of cycle-period time jitters. Aspects relating to calibration of the contention-current generators are also addressed.

### Circuit Description

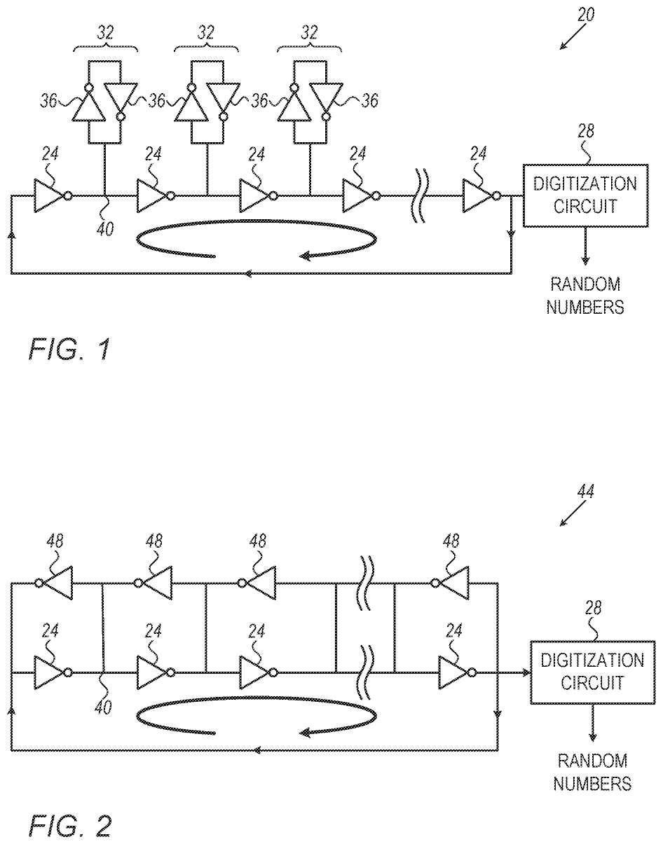

FIG. 1 is a block diagram that schematically illustrates a contention-based Random-Number Generator (RNG) 20, in accordance with an embodiment of the present invention. RNG 20 can be used in various Integrated Circuits (ICs) and other types of electronic devices, such as in secure processors or memories having cryptographic engines that use random-number sequences.

RNG 20 comprises a ring oscillator comprising an odd number of multiple inverters 24 connected in a ring. The ring oscillator is free running, in the sense that inverters 24 are not synchronized to any central clock signal. Each inverter flips the logic state of its output when the voltage at its input reaches a certain threshold, i.e., when the voltage at the output of the preceding inverter reaches a certain threshold. Because of the propagation delay through the inverters and because the odd number of inverters are arranged in a ring configuration, the ring oscillator generates an oscillating signal. Because each of the inverters has intrinsic noise, the cycle period exhibits a certain time jitter.

RNG 20 further comprises a digitization circuit 28 that samples the oscillating signal generated in the ring oscillator, thereby generating a sequence of random numbers. Digitization circuit 28 may use any suitable technique for sampling the oscillating signal. Possible implementations of digitization circuits, also referred to as sampling circuits, are described, for example, in U.S. Pat. No. 10,824,396 and U.S. patent application Ser. No. 17/571,549, filed Jan. 10, 2022, whose disclosures are incorporated herein by reference.

In practice, the amount of time jitter in the cycle period of the oscillating signal is affected by the amount of noise that is present in the signal during the transition periods between logic “0” and “1”. In order to increase this noise, and consequently increase the time jitter of the oscillating signal, RNG 20 further comprises one or more contention-current generators 32.

A given contention-current generator 32 is connected to a circuit node that connects the output of a given inverter 24 in the ring oscillator to the input of the subsequent inverter 24. The left-most contention-current generator 32, for example, is connected to a node marked between two adjacent inverters 24 of the ring oscillator. In the present example, each contention-current generator 32 comprises a bus-holder, i.e., a pair of inverters 36 connected back-to-back (input-to-output). An alternative contention-current generator configuration is presented in FIG. 2 below.

Consider circuit node 40, by way of example. As seen, both the left-most driver 24 and the left-most contention-current generator 32 drive node 40 with current. The current driven by inverter 24 is referred herein to as “drive current”, and the current driven by contention-generator 32 is referred herein to as “contention current”. Contention-current generator is designed so that the contention current (i) opposes the drive current and (ii) is weaker than the drive current. The two conditions should be met at least during the transition periods between “0” and “1” at node 40.

When these conditions are met, the noise level during transitions is increased, thereby increasing the time jitter in the transitions of the oscillating signal. The high time jitter increases the level of randomness in the random-number sequence output by digitization circuit 28.

FIG. 2 is a block diagram that schematically illustrates a contention-based RNG 44, in accordance with another embodiment of the present invention. In the embodiment of FIG. 2, each contention generator comprises a single inverter 48 that drives a respective node with contention current. In contrast to the configuration of FIG. 1, the input to a given inverter 48 is taken from another node downstream in the ring. In the present example, for an inverter 48 that drives a given node in the ring, the input to the inverter 48 is taken from the next node in the ring.

In the embodiment of FIG. 2, too, inverter 48 is designed so that its contention current (i) opposes the drive current of the respective ring inverter 24 and (ii) is weaker than the drive current.

The circuit configurations shown in FIGS. 1 and 2 demonstrate how a contention-current generator can be implemented using at least one buffer that drives the node in question with contention current. As noted above, an inverter is regarded herein as a type of buffer. The configurations shown in FIGS. 1 and 2 are example configurations that are chosen purely for the sake of conceptual clarity. In alternative embodiments, the contention-current generators can be implemented in any other suitable way.

### Example Simulated Performance

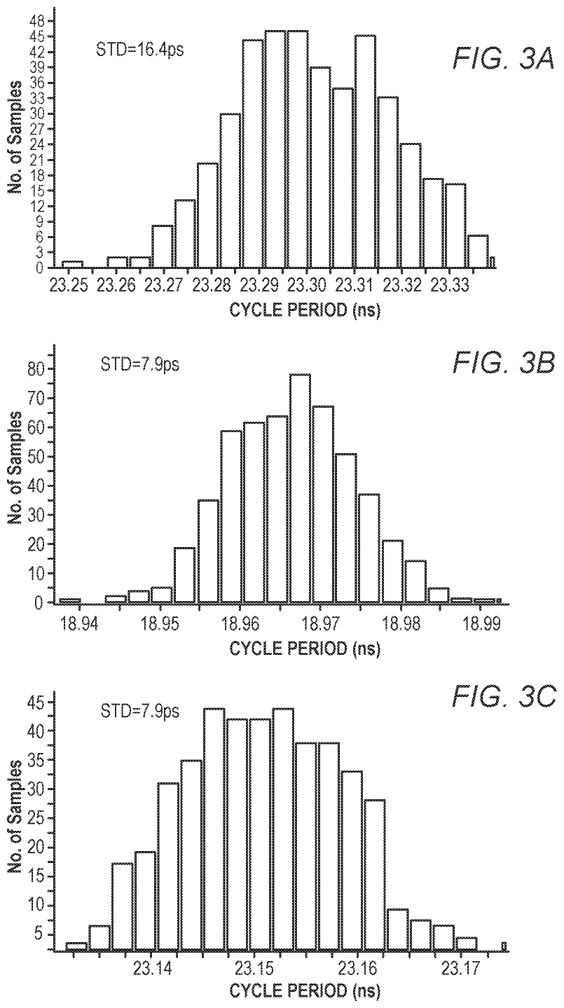

FIGS. 3A-3C are histograms showing simulated performance of a contention-based RNG in accordance with an embodiment of the present invention, and of two non-contention-based RNGs for reference. All three histograms depict the distribution of the cycle period of a ring oscillator. The horizontal axis is divided into ranges (bins) of cycle time in ns, and the vertical axis denotes the number of cycles whose cycle period falls in each bin. A narrow distribution corresponds to small jitter and therefore poor randomness. A wider distribution corresponds to larger jitter and thus better randomness.

FIG. 3A illustrates the jitter for a ring oscillator with contention-current generators, in accordance with the configuration of FIG. 2 above. The ring oscillator in this simulation comprises five inverters 24, and the contention-current generators comprise five respective inverters 48. The ratio of drive-strengths (current-drive capabilities) between inverters 24 and inverters 48 is 2:1, i.e., the contention current is half the drive current (and opposite in polarity). In this configuration the average cycle period is ˜23 ns, and the standard deviation (STD) of the cycle period is ˜16.4 ns.

FIG. 3B illustrates the jitter for a conventional ring oscillator, without contention-current generators. The ring oscillator in this simulation has five inverters 24, and is designed to have a similar equivalent current drive and parasitic load to the oscillator of FIG. 3A above. In this configuration the average cycle period is ˜19 ns, and the standard deviation of the cycle period is ˜7.9 ns.

FIG. 3C illustrates the jitter for another conventional ring oscillator, without contention-current generators. The ring oscillator in the present simulation has fifteen inverters 24, each having a smaller parasitic load compared to the oscillator of FIG. 3A, so as to provide the same average cycle period (23 ns) as the oscillator of FIG. 3A. In this configuration the standard deviation of the cycle period is ˜7.9 ns.

A comparison of FIG. 3A (with contention) to FIGS. 3B and 3C (no contention) demonstrates that, for a comparable ring size and parasitic load, the disclosed technique achieves twice the jitter.

The simulations of FIGS. 3A-3C assume typical operating conditions (voltage and temperature). Additional simulations were conducted for various operating voltages and temperatures. Results were similar, generally providing twice the jitter relative to a comparable conventional ring oscillator.

Yet another simulation (not seen in the figures) simulated a conventional ring oscillator (no contention-current generators) having a similar parasitic load and similar jitter (˜16 ns) to the oscillator (with contention-current generators) of FIG. 3A above. In this configuration the average cycle period is ˜79 ns and the number of inverters is twenty-one. This simulation demonstrates how the disclosed technique reduces the ring size for a given noise level (i.e., for a given randomization level).

### RNG Method Description

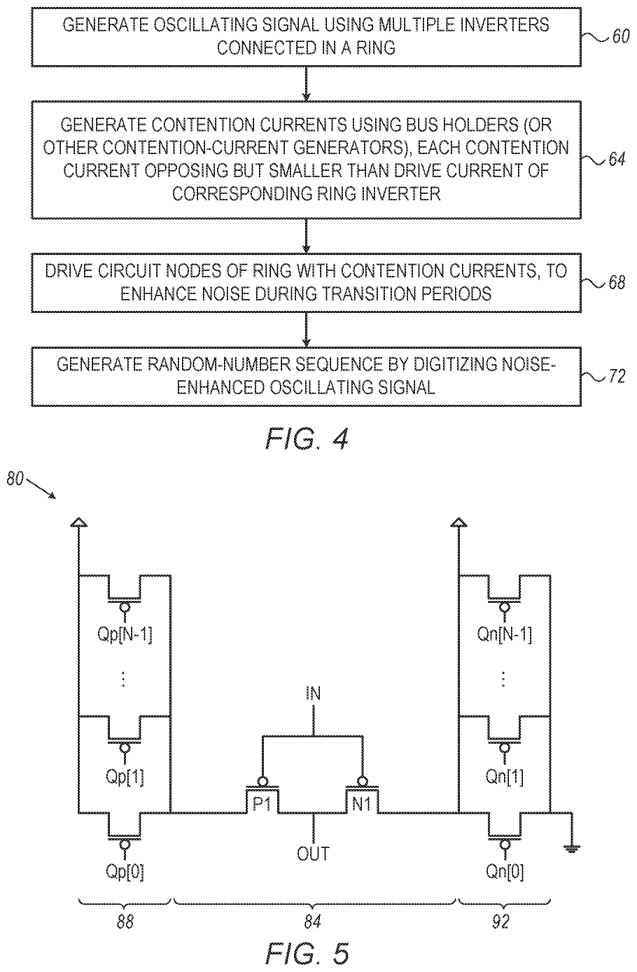

FIG. 4 is a flow chart that schematically illustrates a method for random-number generation, in accordance with an embodiment of the present invention. The method may be carried out by any of the disclosed RNG circuits, e.g., RNG 20 of FIG. 1 or RNG 44 of FIG. 2.

At a signal generation stage 60, the ring oscillator in the RNG generates an oscillating signal. At a contention-current generation stage 64, each contention-current generator of the RNG (e.g., bus holder 32 of FIG. 1 or inverter 48 of FIG. 2) generates a contention current that (i) opposes the drive current of the corresponding ring inverter 24.

At a contention driving stage 68, the contention-current generators drive their respective circuit nodes with the contention currents. At a random-number generation stage 72, digitization circuit 28 of the RNG samples the oscillating signal, whose noise is enhanced due to the contention currents, so as to generate a random-number sequence.

### Drive-Strength Calibration

As explained above, in order to function properly and enhance the randomness of the RNG, the contention current of a given contention-current generator should (i) oppose the drive current of the corresponding ring inverter, and (ii) be weaker than this drive current. Moreover, to provide a high degree of noise enhancement, the contention current should not be too weak. Typically, the ratio between the drive current and the contention current should be in the range of 1.25:1 to 2:1.

In practical implementations, the desired relationship between the contention current and the corresponding drive current (or equivalently, the relationship between the drive-strengths of a contention-current generator and of the corresponding ring inverter) should be maintained over the specified operating conditions of the RNG. Slight deviations from this relationship is usually tolerable, as long as the ratio is not too close to 1:1 (to retain oscillation) and not too far from 1:1 (to retain sufficient noise).

The specified operating conditions may include, for example, process variations, voltage variations and temperature variations (“PVT”).

In some embodiments, the ring inverters and contention-current generators are designed so that the ratio between each drive current and the corresponding contention current remains within a predefined range. In some embodiments, in order to maintain the desired drive-strength ratios, the drive-strengths of the P-channels and N-channels in the ring inverters and in the contention-current generators should be calibrated. Calibration may be performed, for example, during production and/or during normal operation. Any suitable calibration circuitry can be used for this purpose. Drive-strength calibration is also addressed in U.S. Pat. No. 10,824,396, cited above.

FIG. 5 is a block diagram that schematically illustrates a calibration circuit for a contention-current generator, in accordance with embodiments of the present invention. The circuit of FIG. 5 is used for calibrating a buffer 84 (an inverter in the present example) of a contention-current generator, seen at the center of the figure. Buffer 84 may comprise, for example, any of inverters 36 of FIG. 1 or any of inverters 48 of FIG. 2. Buffer 84 comprises two Metal-Oxide Semiconductor Field-Effect Transistors (MOSFETs)—A P-channel MOSFET (PMOS) denoted P1 and an N-channel MOSFET (NMOS) denoted N1.

PMOS P1 is connected to the supply voltage via a bank 88 of N control transistors. Each control transistor in bank 88 can be set to either cut-off or conduction by setting a control signal denoted Qp to either “1” or “0”. The k^{th} control transistor in bank 88 is controlled by a value denoted Qp[k]. The calibration values Qp[0]-Qp[N−1] are typically stored in a register (not seen in the figure). The choice of calibration values Qp[0]-Qp[N−1] determines the amount of current flowing via PMOS P1. Setting a larger number of calibration values to “0” opens a larger number of parallel current paths between P1 and the supply voltage and therefore allows more current to flow, and vice versa.

In a similar fashion, NMOS N1 is connected to ground voltage via a bank 92 of N control transistors. Each control transistor in bank 92 can be set to either cut-off or conduction by setting a control signal denoted Qn to either “1” or “0”. The k^{th} control transistor in bank 92 is controlled by a value denoted Qn[k]. The calibration values Qn[0]-Qn[N−1] are typically stored in a register (not seen in the figure). The choice of calibration values Qn[0]-Qn[N−1] determines the amount of current flowing via NMOS N1. Setting a larger number of calibration values to “1” opens a larger number of parallel current paths between N1 and ground and therefore allows more current to flow, and vice versa.

In some embodiments, all the calibration transistors in a given bank (88 or 92) are similar in size, thereby setting a substantially linear relation between the number of “0”/“1” calibration values and the resulting drive strength. In other embodiments, the calibration transistors in a given bank (88 or 92) can be chosen with different sizes (e.g., powers of two), so as to set other suitable relations between the calibration values and the drive strength.

Typically, although not necessarily, the drive strength of a given control transistor in bank 88 should be similar to the drive strength of the corresponding control transistor in bank 92, for comparable operating conditions (e.g., process corner). A similar relationship is typically used between PMOS P1 and NMOS N1.

The circuit configurations of FIGS. 1, 2 and 5 are example configurations that are chosen purely for the sake of conceptual clarity. Any other suitable configurations can be used in alternative embodiments. The various circuit elements shown in FIGS. 1, 2 and 5 may be implemented using any suitable hardware, such as in one or more Application-Specific Integrated Circuits (ASICs) or Field-Programmable Gate Arrays (FPGAs).

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic circuit for Random Number Generation (RNG), comprising:
multiple inverters connected to one another in a ring and configured to generate an oscillating signal;
a contention-current generator, which is connected to a node at which an output of an inverter of the ring drives an input of a subsequent inverter of the ring with a drive current, the contention-current generator comprising at least a buffer configured to drive the node, at least while a voltage at the node transitions between opposite logic states, with a contention current that opposes the drive current and is weaker than the drive current; and
digitization circuitry, which is configured to generate a sequence of random numbers by sampling the oscillating signal generated in the ring.

2. The electronic circuit according to claim 1, wherein the contention-current generator comprises a bus holder.

3. The electronic circuit according to claim 1, wherein an input of the buffer of the contention-current generator is driven by an output of a downstream inverter of the ring.

4. The electronic circuit according to claim 3, wherein the downstream inverter is the subsequent inverter in the ring.

5. The electronic circuit according to claim 1, wherein the buffer in the contention-current generator has a weaker drive strength than the inverter generating the drive current.

6. The electronic circuit according to claim 1, wherein the contention current is weaker than the drive current by no more than a predefined ratio.

7. The electronic circuit according to claim 1, and comprising a calibration circuit, which is configured to calibrate one or both of (i) the inverter of the ring and (ii) the buffer in the contention-current generator, so as to ascertain that the contention current is weaker than the drive current by no more than a predefined ratio.

8. A method for Random Number Generation (RNG), comprising:
generating an oscillating signal using multiple inverters that are connected to one another in a ring;
using a contention-current generator, which comprises at least a buffer connected to a node at which an output of an inverter of the ring drives an input of a subsequent inverter of the ring with a drive current, driving the node, at least while a voltage at the node transitions between opposite logic states, with a contention current that opposes the drive current and is weaker than the drive current; and
generating a sequence of random numbers by sampling the oscillating signal generated in the ring.

9. The method according to claim 8, wherein the contention-current generator comprises a bus holder.

10. The method according to claim 8, wherein an input of the buffer of the contention-current generator is driven by an output of a downstream inverter of the ring.

11. The method according to claim 10, wherein the downstream inverter is the subsequent inverter in the ring.

12. The method according to claim 8, wherein the buffer in the contention-current generator has a weaker drive strength than the inverter generating the drive current.

13. The method according to claim 8, wherein the contention current is weaker than the drive current by no more than a predefined ratio.

14. The method according to claim 8, and comprising calibrating one or both of (i) the inverter of the ring and (ii) the buffer in the contention-current generator so as to ascertain that the contention current is weaker than the drive current by no more than a predefined ratio.
